(19) United States
(12) Patent Application Publication
(10) Pub. No.: US 2024/0379163 A1
(43) Pub. Date: Nov. 14, 2024

(54) SEMICONDUCTOR DEVICE AND OPERATING METHOD OF THE SAME

(71) Applicant: SK hynix Inc., Gyeonggi-do (KR)

(72) Inventor: Ho Kyun JANG, Gyeonggi-do (KR)

(21) Appl. No.: 18/460,687

(22) Filed: Sep. 5, 2023

(30) Foreign Application Priority Data
May 12, 2023 (KR) 10-2023-0061436

(51) Int. Cl. G11C 16/10; G11C 16/12; G11C 16/14; G11C 16/34

(52) U.S. Cl. CPC G11C 16/102; G11C 16/12; G11C 16/14; G11C 16/3459

(57) ABSTRACT

A semiconductor device may include a memory cell that is connected to a word line and a bit line, a line driving circuit configured to apply to the word line, a program pulse that is enabled to a level of a program voltage and a control circuit configured to control the line driving circuit to: repeatedly apply the program pulse to the word line until a level of a threshold voltage of the memory cell becomes higher than a target level, and adjust, during the repeatedly applying, a level of the program voltage based on a difference between the target level and the level of the threshold voltage.

### CROSS-REFERENCE TO RELATED APPLICATION

This application claims priority under 35 U.S.C. § 119 to Korean Patent Application No. 10-2023-0061436 filed on May 12, 2023, which is incorporated herein by reference in its entirety.

### BACKGROUND

### 1. Technical Field

Embodiments of the present disclosure relate to an integrated circuit technology and, more particularly, to a semiconductor device supporting an ISPP or ISPE and an operating method of the same.

### 2. Related Art

Recently, as an electronic device is reduced in size, has low power consumption and high performance, and is diversified, a semiconductor device capable of storing information is required for various electronic devices, such as computers and portable communication devices. The semiconductor device may be basically divided into a volatile memory device and a nonvolatile memory device. The volatile memory device has a fast data processing speed but has a disadvantage in that the volatile memory device needs to be continuously supplied with power in order to maintain data that has been stored in the volatile memory device. The nonvolatile memory device does not need to be continuously supplied with power in order to maintain data that has been stored in the nonvolatile memory device but has a disadvantage in that the nonvolatile memory device has a slow data processing speed.

Accordingly, the nonvolatile memory device continues to be researched in order to increase data processing speed, that is, an operating speed, and to improve a distribution of threshold voltages of a cell.

### SUMMARY

In an embodiment of the present disclosure, a semiconductor device may include a memory cell that is connected to a word line and a bit line, a line driving circuit configured to apply to the word line, a program pulse that is enabled to a level of a program voltage and a control circuit configured to control the line driving circuit to: repeatedly apply the program pulse to the word line until a level of a threshold voltage of the memory cell becomes higher than a target level, and adjust, during the repeatedly applying, a level of the program voltage based on a difference between the target level and the level of the threshold voltage.

In an embodiment of the present disclosure, a semiconductor device may include a memory cell string that is connected between a bit line and a source line and that comprises a plurality of memory cells, a source voltage application circuit configured to provide the source line with an erase pulse that is enabled to a level of an erase voltage, and a control circuit configured to control the source voltage application circuit to: repeatedly apply the erase pulse to the source line until a level of a threshold voltage of each of the memory cells becomes lower than a target level, and adjust, during the repeatedly applying, a level of the erase voltage based on a difference between the target level and the level of the threshold voltage.

In an embodiment of the present disclosure, an operating method of a semiconductor device may include generating a program pulse according to a step size, applying the program pulse to a memory cell, sensing a level of a threshold voltage of the memory cell, comparing a target level and the level of the threshold voltage, selecting the step size based on a difference between the target level and the level of the threshold voltage, and repeating, until the level of the threshold voltage becomes higher than the target level, the generating, the applying, the sensing, the comparing and the selecting.

In an embodiment of the present disclosure, an operating method of a semiconductor device may include generating an erase pulse according to a step size, applying the erase pulse to a memory cell, sensing a level of a threshold voltage of the memory cell, comparing a target level and the level of the threshold voltage, selecting the step size based on a difference between the target level and the level of the threshold voltage, and repeating, until the level of the threshold voltage becomes lower than the target level, the generating, the applying, the sensing, the comparing and the selecting.

In an embodiment of the present disclosure, an operating method of a semiconductor device may include providing a word line with a verification voltage having a target level, detecting a change in an output of a page buffer that senses a bit line of a memory cell connected to the word line, and changing the verification voltage by a preset voltage level until the change is detected.

### BRIEF DESCRIPTION OF THE DRAWINGS

FIG. 1 is a diagram illustrating a construction of a semiconductor device according to an embodiment of the present disclosure.

FIGS. 2 and 3 are diagrams for describing a program operation and erase operation of the semiconductor device according to an embodiment of the present disclosure.

FIGS. 4 to 7 are flowcharts and timing diagrams for describing an operating method of the semiconductor device according to an embodiment of the present disclosure.

FIGS. 8 to 11 are diagrams for describing voltage increments of program operations or erase operations of the semiconductor device according to an embodiment of the present disclosure.

FIGS. 12 to 15 are diagrams for describing an increment of a voltage application interval according to a program operation or erase operation of the semiconductor device according to an embodiment of the present disclosure.

### DETAILED DESCRIPTION

Hereinafter, embodiments according to the technical spirit of the present disclosure are described with reference to the accompanying drawings.

Embodiments of the present disclosure provide a semiconductor device supporting an improved ISPP or ISPE operation and an operating method of the semiconductor device.

It is possible to improve the speed of a program or erase operation while improving a distribution of threshold voltages of a cell.

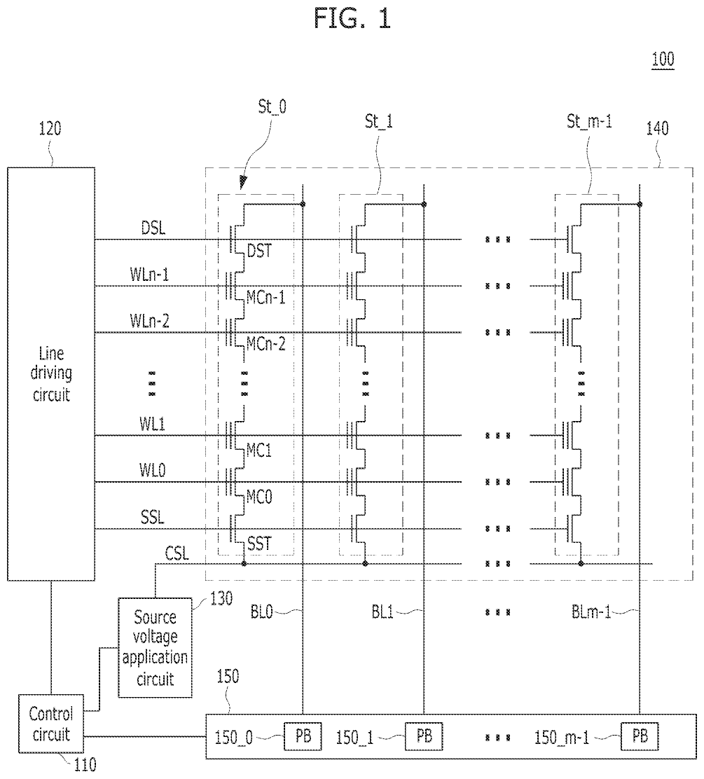

FIG. 1 is a diagram illustrating a construction of a semiconductor device 100 according to an embodiment of the present disclosure.

Referring to FIG. 1, the semiconductor device 100 may include a control circuit 110, a line driving circuit 120, a source voltage application circuit 130, a cell string group 140, and a page buffer group 150.

The control circuit 110 may program data into the cell string group 140 or erase data that has been programmed into the cell string group 140 by controlling the line driving circuit 120, the source voltage application circuit 130, the cell string group 140, and the page buffer group 150.

The line driving circuit 120 may drive a drain selection line DSL, word lines WL0 to WLn−1, and a source selection line SSL to internal voltage levels, respectively, under the control of the control circuit 110. After the start of a program operation, the line driving circuit 120 may apply a program voltage to at least one of the word lines WL0 to WLn−1 as an internal voltage under the control of the control circuit 110. In this case, the level and application time of the program voltage that is applied from the line driving circuit 120 to the word lines WL0 to WLn−1 may be controlled by the control circuit 110. Accordingly, the line driving circuit 120 may apply at least one of the word lines WL0 to WLn−1 with a program pulse that is enabled to the level of the program voltage and that has an enable interval corresponding to the application time of the program voltage.

The source voltage application circuit 130 may apply an internal voltage or a ground voltage to a source line CSL under the control of the control circuit 110. After the start of an erase operation, the source voltage application circuit 130 may apply an erase voltage to the source line CSL as an internal voltage under the control of the control circuit 110. In this case, the level and application time of the erase voltage that is provided from the source voltage application circuit 130 to the source line CSL may be controlled by the control circuit 110. Accordingly, the source voltage application circuit 130 may apply, to the source line CSL, an erase pulse that is enabled to the level of the erase voltage and that has an enable interval corresponding to the application time of the erase voltage.

The cell string group 140 may include a plurality of cell strings St_0 to St_m−1. The plurality of cell strings St_0 to St_m−1 may be connected between respective bit lines BL0 to BLm−1 and the source line CSL. Each of the plurality of cell strings St_0 to St_m−1 may include a drain selection transistor DST, a plurality of cell transistors MC0 to MCn−1, and a source selection transistor SST. In this case, the components of each of the plurality of cell strings St_0 to St_m−1 have only different names of input signals or connected lines and are the same. Accordingly, the components of the cell string St_0, among the plurality of cell strings St_0 to St_m−1, may be representatively described.

The cell string St_0 may include the drain selection transistor DST, the plurality of cell transistors MC0 to MCn−1, and the source selection transistor SST that are connected in series between the bit line BL0 and the source line CSL.

The drain selection transistor DST may have a gate to which the drain selection line DSL is connected, and may have a drain and a source to which the bit line BL0 and the cell transistor MCn−1 are connected, respectively.

The plurality of cell transistors MC0 to MCn−1 may be connected in series between the drain selection transistor DST and the source selection transistor SST. The plurality of word lines WL0 to WLn−1 may be connected to the gates of the plurality of cell transistors MC0 to MCn-1, respectively. In this case, each of the plurality of cell transistors MC0 to MCn−1 may play a role as a memory cell into which data is programmed and from which data is erased. Hereinafter, each of the plurality of cell transistors MC0 to MC_n−1 may be named a memory cell.

The source selection transistor SST may have a gate connected to the source selection line SSL, and may have a drain and a source connected to the cell transistor MC0 and the source line CSL, respectively.

The page buffer group 150 may include a plurality of page buffers (PB) 150_0 to 150_m−1. The plurality of page buffers (PB) 150_0 to 150_m−1 may be connected to the plurality of bit lines BL0 to BLm−1, respectively. Each of the plurality of page buffers (PB) 150_0 to 150_m−1 may detect threshold voltages of the memory cells MC0 to MCm−1, through each of the bit lines BL0 to BLm−1 that have been connected to the page buffers (PB) 150_0 to 150_m−1. For example, each of the plurality of page buffers (PB) 150_0 to 150_m−1 may receive a current flowing into a selected memory cell, among the memory cells MC0 to MC_m−1, through a selected bit line, and may store data having a level according to the received current. More specifically, for example, each of the plurality of page buffers (PB) 150_0 to 150_m−1 may store data having a high level or a low level according to a current that is input through a selected bit line, and may output the stored data as the output of the page buffer. Accordingly, when a verification voltage is applied to a selected word line among the plurality of word lines WL0 to WLn−1, a page buffer that has been connected to a selected bit line, among the plurality of page buffers (PB) 1500 to 150_m−1, may store data having a high level or a low level based on a current that flows from the selected word line to the bit line that is selected through the memory cell, and may output the stored data as the output of the page buffer. Accordingly, the output of the page buffer may mean a state of the memory cell, that is, whether the level of a threshold voltage of the memory cell is higher or lower than the level of the verification voltage. At least one of the plurality of page buffers (PB) 150_0 to 150_m−1 of the page buffer group 150 may sense whether the level of a threshold voltage of a selected memory cell is higher or lower than a target level, and may provide the results of the sensing to the control circuit 110 as the output of the page buffer. Moreover, after the start of an erase operation, at least one of the plurality of page buffers (PB) 150_0 to 150_m−1 may apply an erase voltage to at least one of the bit lines BL0 to BLm−1 under the control of the control circuit 110.

The semiconductor device 100 constructed as above may program at least one of the plurality of memory cells MC0 to MCn−1 by repeatedly providing a program voltage to at least one of the plurality of word lines WL0 to WLn−1 for a predetermined time. At this time, the source line CSL or at least one of the plurality of the bit line BL0 to BLm−1 may have the level of the ground voltage.

The semiconductor device 100 may erase at least one of the plurality of memory cells MC0 to MCn−1 by repeatedly providing an erase voltage to the source line CSL or at least one of the plurality of bit lines BL0 to BLm−1 for a predetermined time. At this time, at least one of the plurality of word lines WL0 to WLn−1 may have the level of the ground voltage.

After the start of a program operation or an erase operation, the control circuit 110 may compare a target level and the level of a sensed threshold voltage of a memory cell, and may select the voltage level and the size of an enable interval of each of a program pulse or an erase pulse, based on a difference between the target level and the level of the threshold voltage of the memory cell. That is, a program pulse or erase pulse based on a voltage level and the size of an interval in which the program pulse or the erase pulse is enabled, which are selected by the control circuit 110, may be provided to the memory cell.

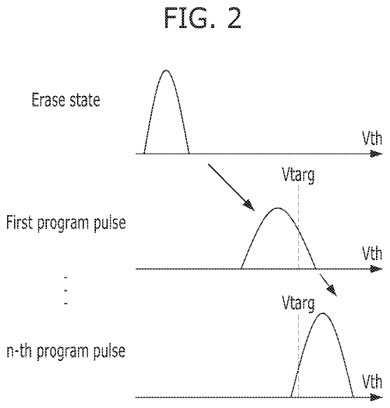

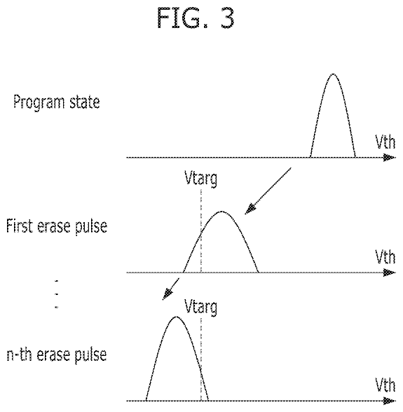

FIGS. 2 and 3 are diagrams for describing a program operation and erase operation of the semiconductor device according to an embodiment of the present disclosure.

FIG. 2 is a diagram for describing the program operation according to an embodiment of the present disclosure.

Referring to FIG. 2, the program operation of the semiconductor device 100 according to an embodiment of the present disclosure may include an operation of sequentially providing a plurality of program pulses to the word line WL until a distribution of threshold voltages of the memory cell MC in an erase state becomes higher than the level of a target voltage Vtarg. In this case, the target voltage Vtarg after the start of the program operation may have a minimum voltage level in the distribution of the threshold voltages of the memory cell in a program state, and may have a voltage level higher than each of the threshold voltages of the memory cells in the erase state.

Furthermore, the voltage level of the program pulse may be the level of a program voltage, and an enable interval of the program pulse may be an interval or time during which the program voltage is applied to the word line WL.

The program operation may mean that the level of the threshold voltage Vth of the memory cell is raised by repeatedly providing the program pulse to the word line WL until the level of the threshold voltage of the memory cell becomes higher than the level of the target voltage Vtarg.

The semiconductor device according to an embodiment of the present disclosure may perform a program operation by changing the voltage level and the size of an enable interval of each of a plurality of program pulses that are provided to a word line, based on a difference between the level of a target voltage and the level of a threshold voltage of the memory cell MC.

FIG. 3 is a diagram for describing an erase operation according to an embodiment of the present disclosure.

Referring to FIG. 3, the erase operation of the semiconductor device 100 according to an embodiment of the present disclosure may include an operation of sequentially providing a plurality of erase pulses to the bit line BL or the source line CSL until a distribution of threshold voltages of the memory cell MC in the program state becomes lower than the level of a target voltage Vtarg. In this case, the target voltage Vtarg after the start of the erase operation may have a maximum voltage level in the distribution of the threshold voltages of the memory cell in the erase state and may have a voltage level lower than each of the threshold voltages of the memory cells in the program state.

Furthermore, the voltage level of an erase pulse may be the level of an erase voltage. An enable interval of the erase pulse may be an interval during which the erase voltage is applied to the bit line BL or the source line CSL.

The erase operation may mean that the level of the threshold voltage Vth of the memory cell is lowered by repeatedly providing the erase pulse to the bit line BL or the source line CSL until the level of the threshold voltage of the memory cell becomes lower than the level of the target voltage Vtarg.

The semiconductor device according to an embodiment of the present disclosure may perform an erase operation by changing the voltage level and the size of an enable interval of each of a plurality of erase pulses that are provided to the bit line or the source line, based on a difference between the level of a target voltage and the level of a threshold voltage of a memory cell.

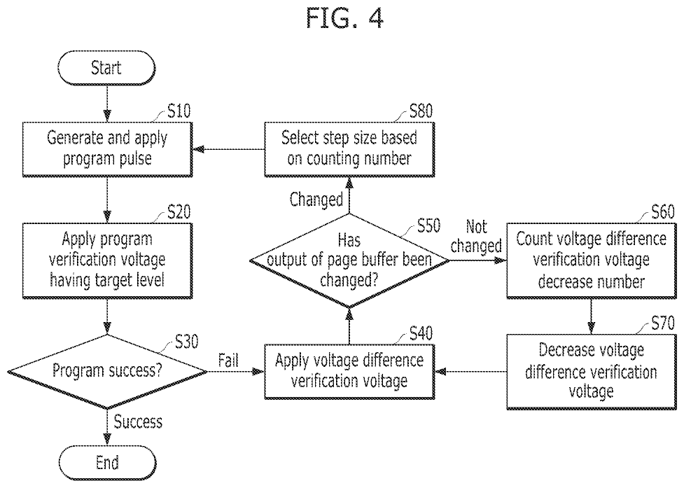

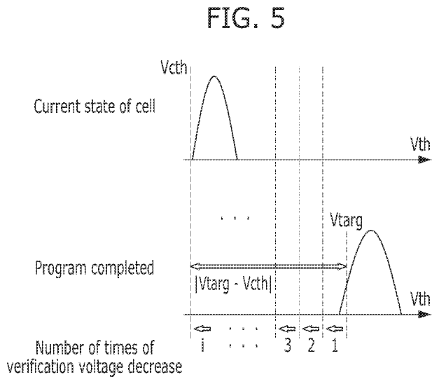

FIGS. 4 and 5 are a flowchart and a diagram for describing an operating method of the semiconductor device according to an embodiment of the present disclosure.

FIG. 4 is a flowchart for describing a program operation of the semiconductor device according to an embodiment of the present disclosure.

Referring to FIG. 4, the program operation of the semiconductor device according to an embodiment of the present disclosure may include operation S10 of generating and applying a program pulse, operation S20 of applying a target level program verification voltage, operation S30 of determining success of a program operation, operation S40 of applying a voltage difference verification voltage, operation S50 of detecting a change in an output from a page buffer, operation S60 of counting a number of times of decreasing the voltage difference verification voltage, operation S70 of decreasing the voltage difference verification voltage, and operation S80 of selecting a step size.

Operation S10 may include generating a program pulse according to a selected step size and providing the generated program pulse to a selected word line. In this case, the step size may include at least one of the voltage level and duration or an enable interval of a program pulse. Furthermore, the threshold voltage of a memory cell that is connected to the selected word line to which the program pulse has been provided may rise.

Operation S20 may include providing the selected word line with a verification voltage having a target level corresponding to a target data level.

Operation S30 may include determining whether a program for the selected memory cell is a success. For example, operation S30 may include a determining whether the level of the threshold voltage of the selected memory cell is higher than the target level.

When it is determined that the level of the threshold voltage of the selected memory cell is higher than the target level in operation S30, the program operation may be determined to be completed and the operating method of the semiconductor device according to an embodiment of the present disclosure may be terminated.

When it is determined that the level of the threshold voltage of the selected memory cell is not higher than the target level in operation S30, operation S40 may be performed.

Operation S40 may include providing the selected word line with a verification voltage having the voltage level according to operation S70.

Operation S50 may include determining whether the output of a page buffer that has sensed a current that flows into a bit line connected to the selected memory cell has been changed due to the verification voltage provided to the selected word line.

If the output of the page buffer has not been changed, operation S60 may be performed.

If the output of the page buffer has been changed, operation S80 may be performed.

Operation S60 may include counting a number of times that the the voltage level of the verification voltage is decreased. The number of times may increase whenever the voltage level of the verification voltage is decreased. Operation S60 may include increasing the number of times that the the voltage level of the verification voltage is decreased whenever the output of the page buffer has not been changed in operation S50.

Operation S70 may include decreasing, by a preset voltage level, the level of the verification voltage that is provided to the selected word line in operation S40. In this case, operation S70 may include decreasing, by the preset voltage level, the voltage level of the verification voltage from the voltage level of the target level.

Operations S40 to S70 may be repeated until the change is detected in the output of the page buffer in operation S50. In this case, the level of the verification voltage at which the change is detected in the output of the page buffer may correspond to the current level of the threshold voltage of the memory cell. That is, the verification voltage may be decreased by a preset voltage level until the output of the page buffer is changed (i.e., until the verification voltage reaches the current level of the threshold voltage of the memory cell) from the level of the verification voltage having the target level. The number of times that the level of the verification voltage has been decreased may be counted. Accordingly, the number of times may correspond to a difference between the target level and the current level of the threshold voltage of the memory cell. The greater the difference between the level of the threshold voltage of the memory cell according to the target level and the current level of the threshold voltage of the memory cell, the greater the number of times. Furthermore, the smaller the difference between the level of the threshold voltage of the memory cell according to the target level and the current level of the threshold voltage of the memory cell, the smaller the number of times. The aforementioned operation may be described in detail with reference to FIG. 5.

Operation S80 may include selecting a step size according to the number of times. For example, in operation S80, a step size of a greater amount may be selected as the number of times is increased.

The loop of operations S10 to S80 may be repeated until the level of the threshold voltage of the selected memory cell is higher than the target level.

In an operating method of the semiconductor device according to an embodiment of the present disclosure, after the start of a program operation, the step size of a program pulse, that is, the change size of the program pulse, based on a difference between the current level of a threshold voltage of a memory cell and a threshold level based on a target data level may be selected until a program is completed. The level of the threshold voltage of the memory cell may be increased based on the selected step size. In this case, the step size may include at least one of the change size of the voltage level of a program pulse and the change size of an enable interval of the program pulse.

FIG. 5 is a diagram for describing an operation capable of obtaining a difference between the level of the threshold voltage of a memory cell according to a current state of the memory cell and a program target level after the start of a program operation according to an embodiment of the present disclosure.

Referring to FIG. 5, the current level Vcth of the threshold voltage according to a current state of a memory cell may be lower than the level of a target voltage Vtarg because the current level Vcth of the threshold voltage according to the current state of the memory cell is in the state before a program is completed.

Operation S70 in FIG. 4 may decrease, step by step by the preset voltage level, a verification voltage from the level of the target voltage Vtarg until it is determined that the output of a page buffer has been changed. Accordingly, when the page buffer outputs an output having a first level when the current level Vcth of the threshold voltage of the memory cell is lower than the level of the verification voltage, the page buffer may output an output having a second level when the level of the verification voltage that is deceased by the preset voltage level becomes lower than the current level Vcth of the threshold voltage of the memory cell. The level of the verification voltage when the level of the output of the page buffer is determined as changed from the first level to the second level may correspond to the current level Vcth of the threshold voltage of the memory cell.

Accordingly, as illustrated in FIG. 5, a difference (IVtarg−VcthI) between the level of the target voltage Vtarg and the current level Vcth of the threshold voltage of the memory cell may correspond to the number of times (1, 2, 3, . . . ) that the level of the verification voltage decreases.

As a result, the semiconductor device according to an embodiment of the present disclosure may select the step size of a program pulse based on the number of times that the verification voltage decreases, may generate a program pulse based on the selected step size, and may provide the program pulse to a selected word line.

Therefore, the semiconductor device according to an embodiment of the present disclosure may select the step size of a program pulse based on a difference between a target level for a program and the current level of a threshold voltage of a memory cell after the start of a program operation, may generate the program pulse having the selected step size, and may program the memory cell.

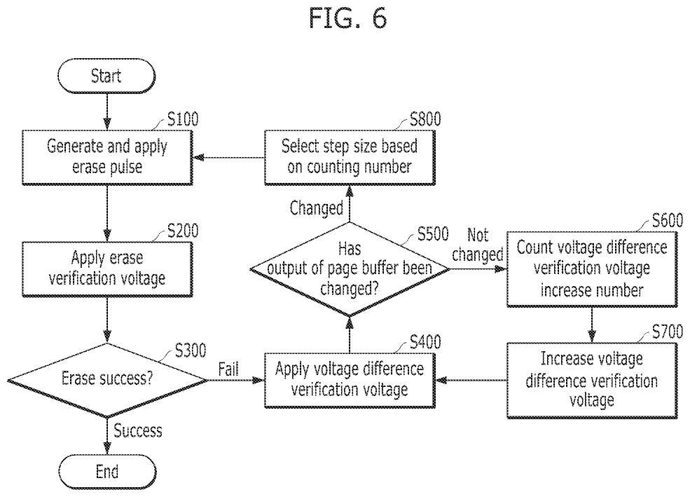

FIG. 6 is a flowchart for describing an erase operation of the semiconductor device according to an embodiment of the present disclosure.

Referring to FIG. 6, the erase operation of the semiconductor device according to an embodiment of the present disclosure may include operation S100 of generating and applying an erase pulse, operation S200 of applying an erase verification verification voltage, operation S300 of determining success of an erase operation, operation S400 of applying a voltage difference verification voltage, operation S500 of detecting a change in an output from a page buffer, operation S600 of counting a number of times of increasing the voltage difference verification voltage, operation S700 of increasing the voltage difference verification voltage, and operation S800 of selecting a step size.

Operation S100 may include generating an erase pulse according to a selected step size and providing the generated erase pulse to a selected bit line or a source line. In this case, the step size may include at least one of the voltage level and duration or an enable interval of the erase pulse.

Operation S200 may include providing a selected word line with a verification voltage having a target level corresponding to an erase state.

Operation S300 may include determining whether the erasing of a selected memory cell is a success. For example, operation S300 may include determining whether the level of the threshold voltage of the selected memory cell is lower than the target level.

When it is determined that the level of the threshold voltage of the selected memory cell is lower than the target level in operation S300, the erase operation may be determined as completed and the operating method of the semiconductor device according to an embodiment of the present disclosure may be terminated.

When it is determined that the level of the threshold voltage of the selected memory cell is not lower than the target level in operation S300, operation S400 may be performed.

Operation S400 may include providing a selected word line with a verification voltage having the voltage level according to operation S700.

Operation S500 may include determining whether the output of a page buffer that has sensed a current that flows into the bit line connected to the selected memory cell has been changed due to the verification voltage provided to the selected word line.

If the output of the page buffer has not been changed, operation S600 may be performed.

If the output of the page buffer has been changed, operation S800 may be performed.

Operation S600 may include counting a number of times that the the voltage level of the verification voltage is increased. The number of times may increase whenever the voltage level of the verification voltage is increased. Operation S600 may include increasing the number of times that the the voltage level of the verification voltage is increased whenever the output of the page buffer has not been changed in operation S500.

Operation S700 may include increasing, by a preset voltage level, the level of the verification voltage that is provided to the selected word line in operation S400. In this case, operation S700 may include increasing, by the preset voltage level, the voltage level of the verification voltage from the target data level.

Operations S400 to S700 may be repeated until the change is detected in the output of the page buffer in operation S500. In this case, the level of the verification voltage at which the change is detected in the output of the page buffer may correspond to the current level of the threshold voltage of the memory cell. That is, the verification voltage may be increased by a preset voltage level until the output of the page buffer is changed (i.e., until the verification voltage reaches the current level of the threshold voltage of the memory cell) from the level of the verification voltage having the target level (i.e., the erase state). The number of times that the level of the verification voltage has been increased may be counted. Accordingly, the number of times may correspond to a difference between the target level and the current level of the threshold voltage of the memory cell. The greater the difference between the level of the threshold voltage of the memory cell according to the target level and the current level of the threshold voltage of the memory cell, the greater the number of times.

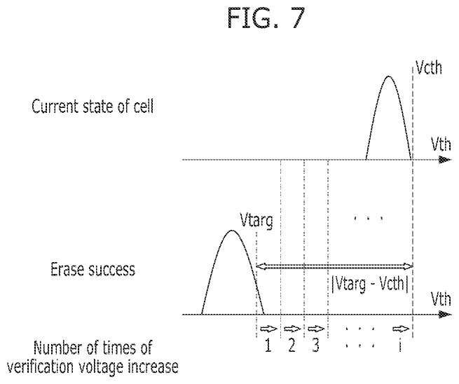

Furthermore, the smaller the difference between the level of the threshold voltage of the memory cell according to the target level and the current level of the threshold voltage of the memory cell, the smaller the number of times. The aforementioned operation is described in detail with reference to FIG. 7.

Operation S800 may include selecting a step size according to the number of times. For example, in operation S800, a step size of a greater amount may be selected as the number of times is increased.

The loop of operations S100 to S800 may be repeated until the level of the threshold voltage of the selected memory cell becomes lower than the target level.

In the operating method of the semiconductor device according to an embodiment of the present disclosure, after the start of an erase operation, the step size of an erase pulse, that is, the change size of the erase pulse, based on a difference between the current level of a threshold voltage of a memory cell and a threshold level based on a target data level may be selected until erase is completed. The level of the threshold voltage of the memory cell may be decreased based on the selected step size. In this case, the step size may include at least one of the change size of the voltage level of the erase pulse and the change size of an enable interval of the erase pulse.

FIG. 7 is a diagram for describing an operation capable of obtaining a difference between the level of the threshold voltage of a memory cell according to a current state of the memory cell and an erase target level after the start of a program operation according to an embodiment of the present disclosure.

Referring to FIG. 7, the current level Vcth of the threshold voltage according to a current state of a memory cell may be higher than the level of a target voltage Vtarg because the current level Vcth of the threshold voltage according to the current state of the memory cell is in the state before erase is completed.

Operation S700 in FIG. 6 may increase, step by step by the preset voltage level, a verification voltage from the level of the target voltage Vtarg until it is determined that the output of a page buffer has been changed. Accordingly, when the page buffer outputs an output having a second level when the current level Vcth of a threshold voltage of a memory cell is higher than the level of the verification voltage, the page buffer may output an output having a first level when the level of the verification voltage that is increased by the preset voltage level becomes higher than the current level Vcth of the threshold voltage of the memory cell. The level of the verification voltage when the level of the output of the page buffer is determined as changed from the second level to the first level may correspond to the current level Vcth of the threshold voltage of the memory cell.

Accordingly, as illustrated in FIG. 7, a difference (IVtarg−VcthI) between the level of the target voltage Vtarg and the current level Vcth of the threshold voltage of the memory cell may correspond to the number of times (1, 2, 3, . . . i) that the level of the verification voltage increases.

As a result, the semiconductor device according to an embodiment of the present disclosure may select the step size of an erase pulse based on the number of times that the verification voltage increases, may generate an erase pulse based on the selected step size, and may provide the erase pulse to a selected bit line or a source line.

Therefore, the semiconductor device according to an embodiment of the present disclosure may select the step size of an erase pulse based on a difference between a target level for erase and the current level of a threshold voltage of a memory cell after the start of an erase operation, may generate the erase pulse having the selected step size, and may erase the memory cell.

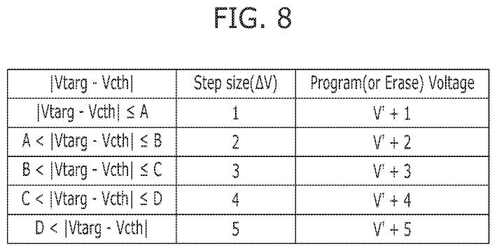

FIGS. 8 to 11 are diagrams for describing variance in voltages for program operations or erase operations of the semiconductor device according to an embodiment of the present disclosure. A program voltage may be a voltage of a program pulse. An erase voltage may be a voltage of an erase pulse. V′ may be a previous voltage of a program pulse or a previous voltage of an erase pulse.

FIG. 8 is a diagram for describing the step size of a program pulse or an erase pulse based on a difference between the level of a target voltage Vtarg and the current level Vcth of a threshold voltage of a memory cell to which the program pulse or the erase pulse has been provided after the start of a program operation or an erase operation and variance ΔV in the level of a program voltage or erase voltage to which the step size has been applied. In this case, A, B, C, and D illustrated in FIG. 8 may have a size relation “A<B<C<D”.

Referring to FIG. 8, a difference between the level of the target voltage Vtarg and the current level Vcth of the threshold voltage of the memory cell may be indicated as IVtarg−VcthI.

IVtarg−VcthI≤A may be a range when the difference between the level of the target voltage Vtarg and the current level Vcth of the threshold voltage of the memory cell is the smallest. At this time, the step size of a program voltage or an erase voltage may be 1, and the program voltage or the erase voltage may have a level (V′+1) that is greater than the level of the previous voltage V′ by an amount corresponding to the step size of 1.

A<IVtarg−VcthI≤B may be a range when the difference between the level of the target voltage Vtarg and the current level Vcth of the threshold voltage of the memory cell is the second smallest. At this time, the step size of a program voltage or an erase voltage may be 2, and the program voltage or the erase voltage may have a level (V′+2) that is greater than the level of the previous voltage V′ by an amount corresponding to the step size of 2.

B<IVtarg−VcthI≤C may be a range when the difference between the level of the target voltage Vtarg and the current level Vcth of the threshold voltage of the memory cell is the third smallest. At this time, the step size of a program voltage or an erase voltage may be 3, and the program voltage or the erase voltage may have a level (V′+3) that is greater than the level of a previous voltage V′ by an amount corresponding to the step size of 3.

C<IVtarg−VcthI≤D may be a range when the difference between the level of the target voltage Vtarg and the current level Vcth of the threshold voltage of the memory cell is the second greatest. At this time, the step size of a program voltage or an erase voltage may be 4, and the program voltage or the erase voltage may have a level (V′+4) that is greater than the level of a previous voltage V′ by an amount corresponding to the step size of 4.

D <IVtarg−VcthI may be a range when the difference between the level of the target voltage Vtarg and the current level Vcth of the threshold voltage of the memory cell is the greatest. At this time, the step size of a program voltage or an erase voltage may be 5, and the program voltage or the erase voltage may have a level (V′+5) that is greater than the level of a previous voltage V′ by an amount corresponding to the step size of 5.

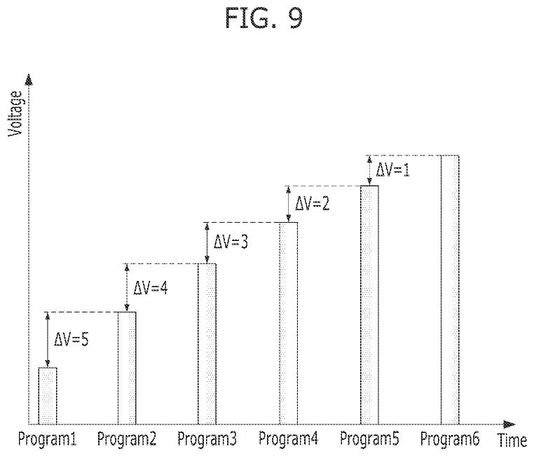

FIGS. 9 to 11 are graphs for describing a voltage of a program pulse, that is, an increment ΔV of a program voltage, in a program operation to which a step size based on a difference between the level of a target voltage Vtarg and the current level Vcth of a threshold voltage of a memory cell has been applied. In this case, for a description of an erase operation, reference may be made to a description of the program operation because the erase operation may have the same method as the program operation.

FIG. 9 is a graph according to a program operation for a normal memory cell.

The first program pulse Program1 may be provided to the memory cell in the erase state. The threshold voltage of the memory cell to which the first program pulse Program1 has been provided may be sensed. At this time, a difference between the current level Vcth of the threshold voltage of the memory cell and the level of a target voltage Vtarg may be greatest. That is, the difference between the level of the target voltage Vtarg and the current level Vcth of the threshold voltage of the memory cell may be a value of a range (D<IVtarg−VcthI), and the step size of the first program pulse may be selected as the amount corresponding to the step size of 5.

The second program pulse Program2 may be provided to the memory cell. At this time, the voltage level of the second program pulse Program2 may be a voltage level (V′(Program1)+ΔV(5)) that is greater than the level of the previous voltage V′ of the program pulse Program1 by the step size (ΔV=5). The threshold voltage of the memory cell to which the second program pulse Program2 has been provided may be sensed. A difference between the current level Vcth of the threshold voltage of the memory cell and the target level Vcth may be the second greatest. That is, the difference between the level of the target voltage Vtarg and the current level Vcth of the threshold voltage of the memory cell may be a value of a range (C<IVtarg−VcthI≤D), and the step size of the second program pulse may be selected as the amount corresponding to the step size of 4.

The third program pulse Program3 may be provided to the memory cell. At this time, the voltage level of the third program pulse Program3 may be a voltage level (V′(Program2)+ΔV(4)) that is greater than the level of the previous voltage V′ of the program pulse Program2 by the step size (ΔV=4). The threshold voltage of the memory cell to which the third program pulse Program3 has been provided may be sensed. A difference between the current level Vcth of the threshold voltage of the memory cell and the level of the target voltage Vtarg may be the third smallest. That is, the difference between the level of the target voltage Vtarg and the current level Vcth of the threshold voltage of the memory cell may be a value of a range (B<IVtarg−VcthI≤C), and the step size of the third program pulse may be selected as the amount corresponding to the step size of 3.

The fourth program pulse Program4 may be provided to the memory cell. At this time, the voltage level of the fourth program pulse Program4 may be a voltage level (V′(Program3)+ΔV(3)) that is greater than the level of the previous voltage V′ of the program pulse Program3 by the step size (ΔV=3). The threshold voltage of the memory cell to which the fourth program pulse Program4 has been provided may be sensed. A difference between the current level Vcth of the threshold voltage of the memory cell and the level of the target voltage Vtarg may be the fourth smallest. That is, the difference between the level of the target voltage Vtarg and the current level Vcth of the threshold voltage of the memory cell may be a value of a range (A<IVtarg−VcthI≤B), and the step size of the fourth program pulse may be selected as the amount corresponding to the step size of 2.

The fifth program pulse Program5 may be provided to the memory cell. At this time, the voltage level of the fifth program pulse Program5 may be a voltage level (V′(Program4)+ΔV(2)) that is greater than the level of the previous voltage V′ of the program pulse Program4 by the step size (ΔV=2). The threshold voltage of the memory cell to which the fifth program pulse Program5 has been provided may be sensed. A difference between the current level Vcth of the threshold voltage of the memory cell and the level of the target voltage Vtarg may be the smallest. That is, the difference between the level of the target voltage Vtarg and the current level Vcth of the threshold voltage of the memory cell may be a value of a range (IVtarg−VcthI≤A), and the step size of the fifth program pulse may be selected as the amount corresponding to the step size of 1.

The sixth program pulse Program6 may be provided to the memory cell. At this time, the voltage level of the sixth program pulse Program6 may be a voltage level (V′(Program5)+ΔV(1)) that is greater than the level of the previous voltage V′ of the program pulse Program5 by the step size (ΔV=1). The threshold voltage of the memory cell to which the sixth program pulse Program6 has been provided may be sensed. The current level Vcth of the threshold voltage of the memory cell may be higher than the level of the target voltage Vtarg, and the program operation may be terminated.

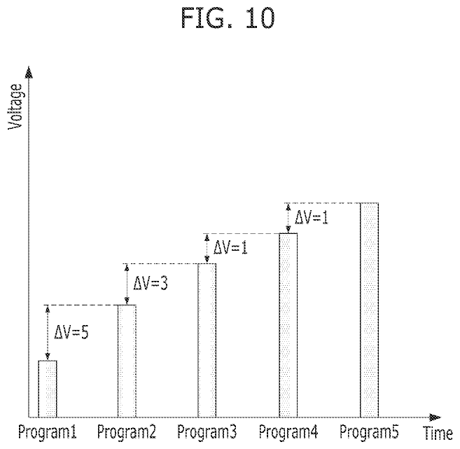

FIG. 10 is a graph according to a program operation for a memory cell (i.e., a fast cell) having a threshold voltage that has a greater change than the threshold voltage of the normal memory cell that has been described with reference to FIG. 9.

The first program pulse Program1 may be provided to the memory cell in the erase state. The threshold voltage of the memory cell to which the first program pulse Program1 has been provided may be sensed. At this time, a difference between the current level Vcth of the threshold voltage of the memory cell and the level of a target voltage Vtarg may be greatest. That is, the difference between the level of the target voltage Vtarg and the current level Vcth of the threshold voltage of the memory cell may be a value of a range (D<IVtarg−VcthI, and the step size of the first program pulse may be selected as the amount corresponding to the step size of 5.

The second program pulse Program2 may be provided to the memory cell. At this time, the voltage level of the second program pulse Program2 may be a voltage level (V′(Program1)+ΔV(5)) that is greater than the level of the previous voltage V′ of the program pulse Program1 by the step size (ΔV=5). The threshold voltage of the memory cell to which the second program pulse Program2 has been provided may be sensed. A difference between the current level Vcth of the threshold voltage of the memory cell and the target level Vcth may be a value of a range (B<IVtarg−VcthI≤C), and the step size of the second program pulse may be selected as the amount corresponding to the step size of 3.

The third program pulse Program3 may be provided to the memory cell. At this time, the voltage level of the third program pulse Program3 may be a voltage level (V′(Program2)+ΔV(3)) that is greater than the level of the previous voltage V′ of the program pulse Program2 by the step size (ΔV=3). The threshold voltage of the memory cell to which the third program pulse Program3 has been provided may be sensed. A difference between the current level Vcth of the threshold voltage of the memory cell and the level of the target voltage Vtarg may be a value of a range (IVtarg−VcthI≤A), and the step size of the third program pulse may be selected as the amount corresponding to the step size of 1.

The fourth program pulse Program4 may be provided to the memory cell. At this time, the voltage level of the fourth program pulse Program4 may be a voltage level (V′(Program3)+ΔV(1)) that is greater than the level of the previous voltage V′ of the program pulse Program3 by the step size (ΔV=1). The threshold voltage of the memory cell to which the fourth program pulse Program4 has been provided may be sensed. A difference between the current level Vcth of the threshold voltage of the memory cell and the level of the target voltage Vtarg may be a value of a range (IVtarg−VcthI≤A), and the step size of the fourth program pulse may be selected as the amount corresponding to the step size of 1.

The fifth program pulse Program5 may be provided to the memory cell. At this time, the voltage level of the fifth program pulse Program5 may be a voltage level (V′(Program4)+ΔV(1)) that is greater than the level of the previous voltage V′ of the program pulse Program4 by the step size (ΔV=1). The threshold voltage of the memory cell to which the fifth program pulse Program5 has been provided may be sensed. The current level Vcth of the threshold voltage of the memory cell may be higher than the level of the target voltage Vtarg, and the program operation may be terminated.

A program operation for a memory cell that has a threshold voltage having a greater change than the threshold voltage of a normal memory cell may be terminated because the level of the threshold voltage of the memory cell becomes higher than the level of a target voltage even though a small number of program pulses are provided to the memory cell.

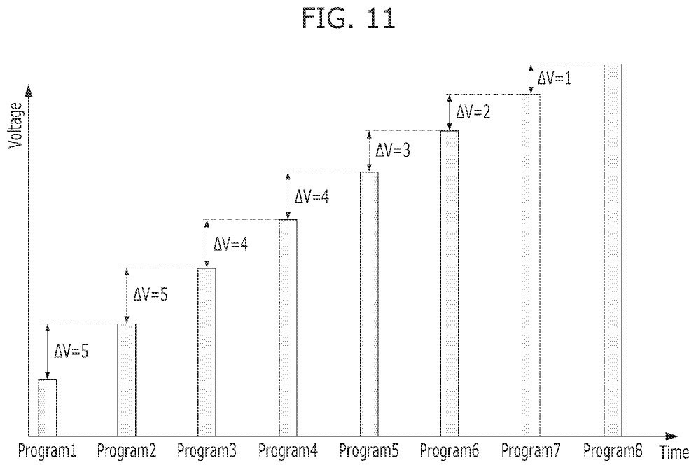

FIG. 11 is a graph according to a program operation for a memory cell (i.e., a slow cell) having a threshold voltage that has a smaller change than the threshold voltage of the normal memory cell that has been described with reference to FIG. 9.

The first program pulse Program1 may be provided to the memory cell in the erase state. The threshold voltage of the memory cell to which the first program pulse Program1 has been provided may be sensed. At this time, a difference between the current level Vcth of the threshold voltage of the memory cell and the level of a target voltage Vtarg may be greatest. That is, the difference between the level of the target voltage Vtarg and the current level Vcth of the threshold voltage of the memory cell may be a value of a range (D<IVtarg−VcthI), and the step size of the first program pulse may be selected as the amount corresponding to the step size of 5.

The second program pulse Program2 may be provided to the memory cell. At this time, the voltage level of the second program pulse Program2 may be a voltage level (V′(Program1)+ΔV(5)) that is greater than the level of the previous voltage V′ of the program pulse Program1 by the step size (ΔV=5). The threshold voltage of the memory cell to which the second program pulse Program2 has been provided may be sensed. A difference between the current level Vcth of the threshold voltage of the memory cell and the target level Vcth may be a value of a range (D<IVtarg−VcthI), and the step size of the second program pulse may be selected as the amount corresponding to the step size of 5.

The third program pulse Program3 may be provided to the memory cell. At this time, the voltage level of the third program pulse Program3 may be a voltage level (V′(Program2)+ΔV(5)) that is greater than the level of the previous voltage V′ of the program pulse Program2 by the step size (ΔV=5). The threshold voltage of the memory cell to which the third program pulse Program3 has been provided may be sensed. A difference between the current level Vcth of the threshold voltage of the memory cell and the level of the target voltage Vtarg may be a value of a range (C<IVtarg−VcthI≤D), and the step size of the third program pulse may be selected as the amount corresponding to the step size of 4.

The fourth program pulse Program4 may be provided to the memory cell. At this time, the voltage level of the fourth program pulse Program4 may be a voltage level (V′(Program3)+ΔV(4)) that is greater than the level of the previous voltage V′ of the program pulse Program3 by the step size (ΔV=4). The threshold voltage of the memory cell to which the fourth program pulse Program4 has been provided may be sensed. A difference between the current level Vcth of the threshold voltage of the memory cell and the level of the target voltage Vtarg may be a value of a range (C<IVtarg−VcthI≤D), and the step size of the fourth program pulse may be selected as the amount corresponding to the step size of 4.

The fifth program pulse Program5 may be provided to the memory cell. At this time, the voltage level of the fifth program pulse Program5 may be a voltage level (V′(Program4)+ΔV(4)) that is greater than the level of the previous voltage V′ of the program pulse Program4 by the step size (ΔV=4). The threshold voltage of the memory cell to which the fifth program pulse Program5 has been provided may be sensed. A difference between the current level Vcth of the threshold voltage of the memory cell and the level of the target voltage Vtarg may be a value of a range (B<IVtarg−VcthI≤C), and the step size of the fifth program pulse may be selected as the amount corresponding to the step size of 3.

The sixth program pulse Program6 may be provided to the memory cell. At this time, the voltage level of the sixth program pulse Program6 may be a voltage level (V′(Program5)+ΔV(3)) that is greater than the level of the previous voltage V′ of the program pulse Program5 by the step size (ΔV=3). The threshold voltage of the memory cell to which the sixth program pulse Program6 has been provided may be sensed. A difference between the current level Vcth of the threshold voltage of the memory cell and the level of the target voltage Vtarg may be a value of a range (A<IVtarg−VcthI≤B), and the step size of the sixth program pulse may be selected as the amount corresponding to the step size of 2.

The seventh program pulse Program7 may be provided to the memory cell. At this time, the voltage level of the seventh program pulse Program7 may be a voltage level (V′(Program6)+ΔV(2)) that is greater than the level of the previous voltage V′ of the program pulse Program6 by the step size (ΔV=2). The threshold voltage of the memory cell to which the seventh program pulse Program7 has been provided may be sensed. A difference between the current level Vcth of the threshold voltage of the memory cell and the level of the target voltage Vtarg may be a value of a range (IVtarg−VcthI≤A), and the step size of the seventh program pulse may be selected as the amount corresponding to the step size of 1.

The eighth program pulse Program8 may be provided to the memory cell. At this time, the voltage level of the eighth program pulse Program8 may be a voltage level (V′(Program7)+ΔV(1)) that is greater than the level of the previous voltage V′ of the program pulse Program7 by the step size (ΔV=1). The threshold voltage of the memory cell to which the eighth program pulse Program7 has been provided may be sensed. The current level Vcth of the threshold voltage of the memory cell may be higher than the level of the target voltage Vtarg, and the program operation may be terminated.

As described with reference to FIGS. 9 to 11, the semiconductor device according to an embodiment of the present disclosure can reduce the number of times that a program pulse is provided, compared to a case in which a program operation is performed on a normal memory cell, after the start of a program operation for a memory cell that has the level of a threshold voltage having a greater change than the level of a threshold voltage of the normal memory cell, by selecting an increment of the voltage level of a program pulse based on a difference between the level of the threshold voltage of the memory cell to which a program pulse has been provided and the level of a target voltage for a program. Furthermore, the semiconductor device according to an embodiment of the present disclosure can increase its program operating speed because the number of times that a program voltage having a high voltage level is provided to a memory cell is increased compared to a case in which a program operation is performed on a normal memory cell, after the start of a program operation for the memory cell that has the level of a threshold voltage having a smaller change than the level of a threshold voltage of the normal memory cell.

As a result, the semiconductor device according to an embodiment of the present disclosure can have a fast program operating speed compared to a program operation method (e.g., the existing ISPP) in which a voltage increment of a program pulse is constant.

Furthermore, even in an erase operation, the step size of an erase pulse may be selected and an increment of the level of an erase voltage may be controlled in the same manner as the program operation as described above, except that the program pulse is provided to the word line and the erase pulse is provided to the bit line or the source line.

Accordingly, the semiconductor device according to an embodiment of the present disclosure can have a fast erase operating speed compared to an erase operation method (e.g., the existing ISPE) in which a voltage increment of an erase pulse is constant.

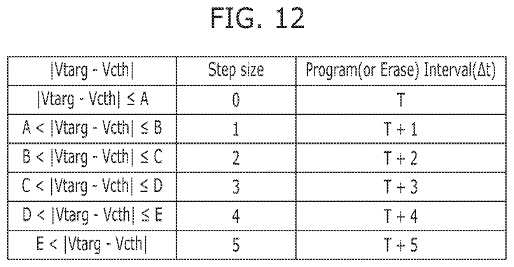

FIGS. 12 to 15 are diagrams for describing variance in the size of an interval in which a voltage is applied according to a program operation or erase operation of the semiconductor device according to an embodiment of the present disclosure. A program voltage may be a voltage having a program pulse. An erase voltage may be a voltage having an erase pulse. Furthermore, an interval in which a program voltage is applied to a word line may be an interval in which a program pulse is enabled. An interval in which an erase voltage is applied to the bit line or the source line may be an interval in which an erase pulse is enabled. T may be a basic size of the interval in which the program pulse or the erase pulse is enabled.

FIG. 12 is a diagram for describing a step size based on a difference between the level of a target voltage Vtarg after the start of a program operation or an erase operation and the current level Vcth of the threshold voltage of a memory cell to which a program pulse or an erase pulse has been provided and variance Δt in the size of an interval in which a program pulse to which the step size has been applied is enabled or an interval in which an erase pulse to which the step size has been applied is enabled. In this case, A, B, C, D, and E illustrated in FIG. 12 may have a size relation “A<B<C<D<E”.

Referring to FIG. 12, the difference between the level of the target voltage Vtarg and the current level Vcth of the threshold voltage of the memory cell may be indicated as IVtarg−VcthI.

IVtarg−VcthI≤A may be a range when the difference between the level of the target voltage Vtarg and the current level Vcth of the threshold voltage of the memory cell is the smallest. At this time, the step size of a program pulse or an erase pulse may be 0. Variance in the application time of a program voltage or an erase voltage, that is, variance in the size of an interval in which the program pulse or the erase pulse is enabled, may correspond to a step size 0. The size Δt of the interval in which the program pulse or the erase pulse is enabled may be the basic size T.

A<IVtarg−VcthI≤B may be a range when the difference between the level of the target voltage Vtarg and the current level Vcth of the threshold voltage of the memory cell is the second smallest. At this time, the step size of a program pulse or an erase pulse may be 1.

Variance in the application time of a program voltage or an erase voltage, that is, variance in the size of an interval in which the program pulse or the erase pulse is enabled, may correspond to an amount corresponding to the step size of 1. The size Δt of the interval in which the program pulse or the erase pulse is enabled may be a size T+1 that is greater than the basic size T by the amount corresponding to the step size of 1.

B<IVtarg−VcthI≤C may be a range when the difference between the level of the target voltage Vtarg and the current level Vcth of the threshold voltage of the memory cell is the third smallest. At this time, the step size of a program pulse or an erase pulse may be 2.

Variance in the application time of a program voltage or an erase voltage, that is, variance in the size of an interval in which the program pulse or the erase pulse is enabled, may correspond to an amount corresponding to the step size of 2. The size Δt of the interval in which the program pulse or the erase pulse is enabled may be a size T+2 that is greater than the basic size T by the amount corresponding to the step size of 2.

C<IVtarg−VcthI≤D may be a range when the difference between the level of the target voltage Vtarg and the current level Vcth of the threshold voltage of the memory cell is the third greatest. At this time, the step size of a program pulse or an erase pulse may be 3.

Variance in the application time of a program voltage or an erase voltage, that is, variance in the size of an interval in which the program pulse or the erase pulse is enabled, may correspond to an amount corresponding to the step size of 3. The size Δt of the interval in which the program pulse or the erase pulse is enabled may be a size T+3 that is greater than the basic size T by the amount corresponding to the step size of 3.

D<IVtarg−VcthI E may be a range when the difference between the level of the target voltage Vtarg and the current level Vcth of the threshold voltage of the memory cell is the second largest. At this time, the step size of a program pulse or an erase pulse may be 4.

Variance in the application time of a program voltage or an erase voltage, that is, variance in the size of an interval in which the program pulse or the erase pulse is enabled, may correspond to an amount corresponding to the step size of 4. The size Δt of the interval in which the program pulse or the erase pulse is enabled may be a size T+4 that is greater than the basic size T by the amount corresponding to the step size of 4.

E <IVtarg−VcthI may be a range when the difference between the level of the target voltage Vtarg and the current level Vcth of the threshold voltage of the memory cell is the greatest. At this time, the step size of a program pulse or an erase pulse may be 5. Variance in the application time of a program voltage or an erase voltage, that is, variance in the size of an interval in which the program pulse or the erase pulse is enabled, may correspond to an amount corresponding to the step size of 5. The size Δt of the interval in which the program pulse or the erase pulse is enabled may be a size (T+5) that is greater than the basic size T by the amount corresponding to the step size of 5.

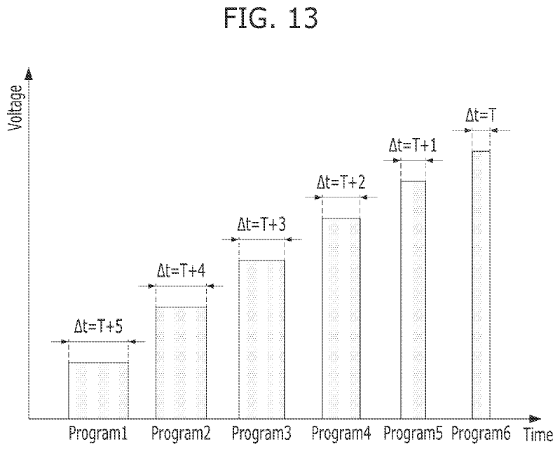

FIGS. 13 to 15 are graphs for describing the size of an interval in which a program pulse is enabled, that is, the application time Δt of a program voltage, in a program operation to which a step size based on a difference between the level of a target voltage Vtarg and the current level Vcth of the threshold voltage of a memory cell has been applied. In this case, for a description of an erase operation, reference may be made to the program operation because the erase operation may have the same method as the program operation. Furthermore, the voltage level of the program pulse may become higher as the program pulse is repeatedly provided to the memory cell.

FIG. 13 is a graph according to a program operation for a normal memory cell.

The first program pulse Program1 may be provided to the memory cell in the erase state. The size of an interval in which the first program pulse Program1 is enabled may be an enable interval Δt having a maximum size (T+5). The threshold voltage of the memory cell to which the first program pulse Program1 has been provided may be sensed. At this time, a difference between the current level Vcth of the threshold voltage of the memory cell and the level of the target voltage Vtarg may be the second greatest. That is, the difference between the level of the target voltage Vtarg and the current level Vcth of the threshold voltage of the memory cell may be a value of a range (D<IVtarg−VcthI E), and the step size of the first program pulse may be selected as the amount corresponding to the step size of 4.

The second program pulse Program2 may be provided to the memory cell. At this time, an interval in which the second program pulse Program2 is enabled may be an enable interval (Δt=T+4) that is greater than the basic size T by the amount corresponding to the step size of 4. The threshold voltage of the memory cell to which the second program pulse Program2 has been provided may be sensed. A difference between the current level Vcth of the threshold voltage of the memory cell and the target level Vcth may be the third greatest. That is, the difference between the level of the target voltage Vtarg and the current level Vcth of the threshold voltage of the memory cell may be a value of a range (C<IVtarg−VcthI≤D), and the step size of the second program pulse may be selected as the amount corresponding to the step size of 3.

The third program pulse Program3 may be provided to the memory cell. At this time, an interval in which the third program pulse Program3 is enabled may be an enable interval (Δt=T+3) that is greater than the basic size T by the amount corresponding to the step size of 3. The threshold voltage of the memory cell to which the third program pulse Program3 has been provided may be sensed. A difference between the current level Vcth of the threshold voltage of the memory cell and the level of the target voltage Vtarg may be the third smallest. That is, the difference between the level of the target voltage Vtarg and the current level Vcth of the threshold voltage of the memory cell may be a value of a range (B<IVtarg−VcthI≤C), and the step size of the third program pulse may be selected as the amount corresponding to the step size of 2.

The fourth program pulse Program4 may be provided to the memory cell. At this time, an interval in which the fourth program pulse Program4 is enabled may be an enable interval (Δt=T+2) that is greater than the basic size T by the amount corresponding to the step size of 2. The threshold voltage of the memory cell to which the fourth program pulse Program4 has been provided may be sensed. A difference between the current level Vcth of the threshold voltage of the memory cell and the level of the target voltage Vtarg may be the second smallest. That is, the difference between the level of the target voltage Vtarg and the current level Vcth of the threshold voltage of the memory cell may be a value of a range (A<IVtarg−VcthI≤B), and the step size of the fourth program pulse may be selected as the amount corresponding to the step size of 1.

The fifth program pulse Program5 may be provided to the memory cell. At this time, an interval in which the fifth program pulse Program5 is enabled may be an enable interval (Δt=T+1) that is greater than the basic size T by the amount corresponding to the step size of 1. The threshold voltage of the memory cell to which the fifth program pulse Program5 has been provided may be sensed. A difference between the current level Vcth of the threshold voltage of the memory cell and the level of the target voltage Vtarg may be the smallest. That is, the difference between the level of the target voltage Vtarg and the current level Vcth of the threshold voltage of the memory cell may be a value of a range (IVtarg−VcthI≤A), and the step size of the fifth program pulse may be selected as the amount corresponding to the step size of 0, i.e., the basic size T.

The sixth program pulse Program6 may be provided to the memory cell. At this time, an interval in which the sixth program pulse Program6 is enabled may be the basic size T. The threshold voltage of the memory cell to which the sixth program pulse Program6 has been provided may be sensed. The current level Vcth of the threshold voltage of the memory cell may be higher than the level of the target voltage Vtarg, and the program operation may be terminated.

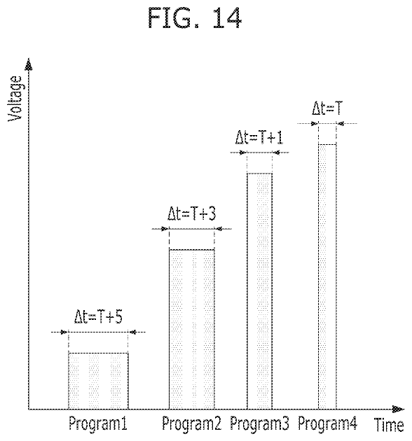

FIG. 14 is a graph according to a program operation for a memory cell (i.e., a fast cell) having a threshold voltage that has a greater change than the threshold voltage of the normal memory cell that has been described with reference to FIG. 13.

The first program pulse Program1 may be provided to the memory cell in the erase state. The size of an interval in which the first program pulse Program1 is enabled may be an enable interval Δt having a maximum size (T+5). The threshold voltage of the memory cell to which the first program pulse Program1 has been provided may be sensed. At this time, a difference between the current level Vcth of the threshold voltage of the memory cell and the target level may be the third greatest. That is, the difference between the level of the target voltage Vtarg and the current level Vcth of the threshold voltage of the memory cell may be a value of a range (C<IVtarg−VcthI≤D), and the step size of the first program pulse may be selected as the amount corresponding to the step size of 3.

The second program pulse Program2 may be provided to the memory cell. At this time, an interval in which the second program pulse Program2 is enabled may be an enable interval (Δt=T+3) that is greater than the basic size T by the amount corresponding to the step size of 3. The threshold voltage of the memory cell to which the second program pulse Program2 has been provided may be sensed. A difference between the current level Vcth of the threshold voltage of the memory cell and the target level Vcth may be a value of a range (A <IVtarg−VcthI≤B), and the step size of the second program pulse may be selected as the amount corresponding to the step size of 1.

The third program pulse Program3 may be provided to the memory cell. At this time, an interval in which the third program pulse Program3 is enabled may be an enable interval (Δt=T+1) that is greater than the basic size T by the amount corresponding to the step size of 1. The threshold voltage of the memory cell to which the third program pulse Program3 has been provided may be sensed. A difference between the current level Vcth of the threshold voltage of the memory cell and the level of the target voltage Vtarg may be a value of a range (IVtarg−VcthI≤A), and the step size of the third program pulse may be selected as the amount corresponding to the step size of 0, i.e., the basic size T.

The fourth program pulse Program4 may be provided to the memory cell. At this time, an interval in which the fourth program pulse Program4 is enabled may be an enable interval (Δt=T+0) having the basic size T. The threshold voltage of the memory cell to which the fourth program pulse Program4 has been provided may be sensed. The current level Vcth of the threshold voltage of the memory cell may be higher than the level of the target voltage Vtarg, and the program operation may be terminated.

Not only the voltage level of a program pulse, but the size of an interval in which the program pulse is enabled may be determined based on a difference between the current level Vcth of the threshold voltage of a memory cell and the level of a target voltage Vtarg. That is, the time when a program voltage is provided to the memory cell may be determined based on a difference between the current level Vcth of the threshold voltage of the memory cell and the level of the target voltage Vtarg. Furthermore, a distribution of threshold voltages of a memory cell, which has a great change, can be improved by decreasing the time during which a program voltage is applied as the number of times that the program pulse is provided to the memory cell is increased, but decreasing the time based on a difference between the current level Vcth of the threshold voltage of the memory cell and the level of a target voltage Vtarg.

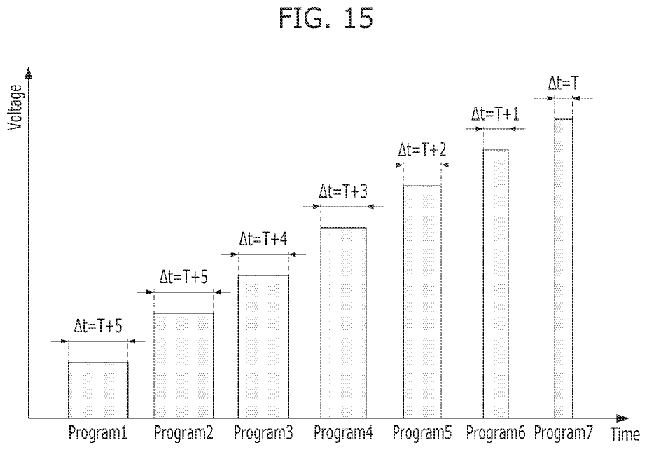

FIG. 15 is a graph according to a program operation for a memory cell (i.e., a slow cell) having a threshold voltage that has a smaller change than the threshold voltage of the normal memory cell that has been described with reference to FIG. 13.

The first program pulse Program1 may be provided to the memory cell in the erase state. The size of an interval in which the first program pulse Program1 is enabled may be an enable interval Δt having a maximum size (T+5). The threshold voltage of the memory cell to which the first program pulse Program1 has been provided may be sensed. At this time, a difference between the current level Vcth of the threshold voltage of the memory cell and the level of the target voltage Vtarg may be greatest. That is, the difference between the level of the target voltage Vtarg and the current level Vcth of the threshold voltage of the memory cell may be a value of a range (E<IVtarg−VcthI), and the step size of the first program pulse may be selected as the amount corresponding to the step size of 5.

The second program pulse Program2 may be provided to the memory cell. At this time, an interval in which the second program pulse Program2 is enabled may be an enable interval (Δt=T+5) that is greater than the basic size T by the amount corresponding to the step size of 5. The threshold voltage of the memory cell to which the second program pulse Program2 has been provided may be sensed. At this time, a difference between the current level Vcth of the threshold voltage of the memory cell and the level of the target voltage Vtarg may be a value of a range (D<IVtarg−VcthI E), and the step size of the second program pulse may be selected as the amount corresponding to the step size of 4.

The third program pulse Program3 may be provided to the memory cell. At this time, an interval in which the third program pulse Program3 is enabled may be an enable interval (Δt=T+4) that is greater than the basic size T by the amount corresponding to the step size of 4. The threshold voltage of the memory cell to which the third program pulse Program3 has been provided may be sensed. At this time, a difference between the current level Vcth of the threshold voltage of the memory cell and the level of the target voltage Vtarg may be a value of a range (C<IVtarg−VcthI≤D), and the step size of the third program pulse may be selected as the amount corresponding to the step size of 3.

The fourth program pulse Program4 may be provided to the memory cell. At this time, an interval in which the fourth program pulse Program4 is enabled may be an enable interval (Δt=T+3) that is greater than the basic size T by the amount corresponding to the step size of 3. The threshold voltage of the memory cell to which the fourth program pulse Program4 has been provided may be sensed. At this time, a difference between the current level Vcth of the threshold voltage of the memory cell and the level of the target voltage Vtarg may be a value of a range (B<IVtarg−VcthI≤C), and the step size of the fourth program pulse may be selected as the amount corresponding to the step size of 2.

The fifth program pulse Program5 may be provided to the memory cell. At this time, an interval in which the fifth program pulse Program5 is enabled may be an enable interval (Δt=T+2) that is greater than the basic size T by the amount corresponding to the step size of 2. The threshold voltage of the memory cell to which the fifth program pulse Program5 has been provided may be sensed. At this time, a difference between the current level Vcth of the threshold voltage of the memory cell and the level of the target voltage Vtarg may be a value of a range (A<IVtarg−VcthI≤B), and the step size of the fifth program pulse may be selected as the amount corresponding to the step size of 1.

The sixth program pulse Program6 may be provided to the memory cell. At this time, an interval in which the sixth program pulse Program6 is enabled may be an enable interval (Δt=T+1) that is greater than the basic size T by the amount corresponding to the step size of 1. The threshold voltage of the memory cell to which the sixth program pulse Program6 has been provided may be sensed. At this time, a difference between the current level Vcth of the threshold voltage of the memory cell and the level of the target voltage Vtarg may be a value of a range (IVtarg−VcthI≤A), and the step size of the sixth program pulse may be selected as the amount corresponding to the step size of 0, i.e., the basic size T.

The seventh program pulse Program7 may be provided to the memory cell. At this time, an interval in which the seventh program pulse Program7 is enabled may be an enable interval (Δt=T+0) having the basic size T. The threshold voltage of the memory cell to which the seventh program pulse Program7 has been provided may be sensed. The current level Vcth of the threshold voltage of the memory cell may be higher than the level of the target voltage Vtarg, and the program operation may be terminated.

As described with reference to FIGS. 13 to 15, the semiconductor device according to an embodiment of the present disclosure can select variance in the interval in which a program pulse is enabled, based on a difference between the level of the threshold voltage of a memory cell to which a program pulse has been provided and the level of a target voltage for a program. Accordingly, an interval in which a program pulse is enabled can be further decreased compared to a case in which a program operation for a normal memory cell is performed, after the start of a program operation for a memory cell having the level of a threshold voltage that has a greater change than the threshold voltage of the normal memory cell. Accordingly, a distribution of the threshold voltages of the memory cell can be improved. Furthermore, a program pulse having a longer enable interval can be provided compared to a case in which a program operation for a normal memory cell is performed, after the start of a program operation for a memory cell having the level of a threshold voltage that has a smaller change than the threshold voltage of the normal memory cell. Accordingly, the program speed of the memory cell can be increased.

As a result, the semiconductor device according to an embodiment of the present disclosure can improve a program operating speed and a distribution of threshold voltages of a memory cell, compared to a program operation method (i.e., the existing ISPP) in which an interval in which a program pulse is enabled is constant.

Furthermore, as described above, even in an erase operation, the step size of an erase pulse may be selected and the application time of an erase voltage may be controlled in the same manner as the program operation as described above, except that the program pulse is provided to the word line and the erase pulse is provided to the bit line or the source line.

Accordingly, the semiconductor device according to an embodiment of the present disclosure can improve an erase operating speed and a distribution of threshold voltages of a memory cell, compared to an erase operation method (i.e., the existing ISPE) in which an interval in which an erase pulse is enabled is constant.

Although embodiments according to the technical spirit of the present disclosure have been described above with reference to the accompanying drawings, the embodiments have been provided to merely describe embodiments according to the concept of the present disclosure, and the present disclosure is not limited to the embodiments.

A person having ordinary knowledge in the art to which the present disclosure pertains may substitute, modify, and change the embodiments in various ways without departing from the technical spirit of the present disclosure written in the following claims. Such substitutions, modifications, and changes may be said to belong to the scope of the present disclosure. Furthermore, the embodiment may be combined to form additional embodiments.

What is claimed is:

1. A semiconductor device comprising:
a memory cell that is connected to a word line and a bit line;
a line driving circuit configured to apply to the word line, a program pulse that is enabled to a level of a program voltage; and
a control circuit configured to control the line driving circuit to:
repeatedly apply the program pulse to the word line until a level of a threshold voltage of the memory cell becomes higher than a target level, and
adjust, during the repeatedly applying, a level of the program voltage based on a difference between the target level and the level of the threshold voltage.

2. The semiconductor device of claim 1, wherein the control circuit controls the line driving circuit to adjust the level of the program voltage by a greater amount as the difference is greater.

3. The semiconductor device of claim 1, wherein the control circuit controls the line driving circuit to adjust the level of the program voltage by a lesser amount as the difference is less.

4. The semiconductor device of claim 1, wherein the control circuit is further configured to control the line driving circuit to adjust a time amount of the applying the program voltage based on the difference.

5. The semiconductor device of claim 4, wherein the control circuit controls the line driving circuit to adjust the time amount by a greater amount as the difference is greater.

6. The semiconductor device of claim 4, wherein the control circuit controls the line driving circuit to adjust the time amount by a lesser amount as the difference is less.

7. A semiconductor device comprising:
a memory cell string that is connected between a bit line and a source line and that comprises a plurality of memory cells;
a source voltage application circuit configured to provide the source line with an erase pulse that is enabled to a level of an erase voltage; and
a control circuit configured to control the source voltage application circuit to:
repeatedly apply the erase pulse to the source line until a level of a threshold voltage of each of the memory cells becomes lower than a target level, and
adjust, during the repeatedly applying, a level of the erase voltage based on a difference between the target level and the level of the threshold voltage.

8. The semiconductor device of claim 7,
further comprising a page buffer configured to provide the erase pulse to the bit line,
wherein the control circuit is further configured to control the page buffer to adjust the level of the erase voltage based on the difference.

9. The semiconductor device of claim 7, wherein the control circuit controls the source voltage application circuit to adjust the level of the erase voltage by a greater amount as the difference is greater and by a lesser amount as the difference is less.

10. The semiconductor device of claim 7, wherein the control circuit is further configured to control the source voltage application circuit to adjust a time amount of the applying the erase voltage based on the difference.

11. The semiconductor device of claim 10, wherein the control circuit controls the source voltage application circuit to adjust the time amount by a greater amount as the difference is greater and by a lesser amount as the difference is less.

12. An operating method of a semiconductor device, the operating method comprising:
generating a program pulse according to a step size;
applying the program pulse to a memory cell;
sensing a level of a threshold voltage of the memory cell;
comparing a target level and the level of the threshold voltage;
selecting the step size based on a difference between the target level and the level of the threshold voltage; and
repeating, until the level of the threshold voltage becomes higher than the target level, the generating, the applying, the sensing, the comparing and the selecting.

13. The operating method of claim 12, wherein the generating comprises at least one of:
changing a voltage level of the program pulse according to the step size; and
changing duration of the program pulse according to the step size.

14. The operating method of claim 12, wherein the comparing of the target level and the level of the threshold voltage comprises:
determining sizes of the target level and the level of the threshold voltage, and
calculating the difference between the target level and the level of the threshold voltage.

15. The operating method of claim 14, wherein the determining of the sizes of the target level and the level of the threshold voltage comprises:
terminating a program operation when the level of the threshold voltage is higher than the target level, and
performing the selecting of the step size when a level of the sensed threshold voltage is lower than the target level.

16. The operating method of claim 12, wherein the selecting of the step size comprises:
selecting the step size of a greater amount as the difference is greater; and
selecting the step size of a lesser amount as the difference is less.

17. An operating method of a semiconductor device, the operating method comprising:
generating an erase pulse according to a step size;
applying the erase pulse to a memory cell;
sensing a level of a threshold voltage of the memory cell;
comparing a target level and the level of the threshold voltage;
selecting the step size based on a difference between the target level and the level of the threshold voltage; and
repeating, unitl the level of the threshold voltage becomes lower than the target level, the generating, the applying, the sensing, the comparing and the selecting.

18. The operating method of claim 17, wherein the generating comprises at least one of:
changing a voltage level of the erase pulse according to the step size; and
changing duration of the erase pulse according to the step size.

19. The operating method of claim 17, wherein the comparing of the target level and the level of the threshold voltage comprises:
determining sizes of the target level and the level of the threshold voltage, and
calculating a difference between the target level and the level of the threshold voltage.

20. The operating method of claim 19, wherein the determining of the sizes of the target level and the level of the threshold voltage comprises:
terminating an erase operation when the level of the threshold voltage is lower than the target level, and
performing the selecting of the step size when the level of the threshold voltage is higher than the target level.

21. The operating method of claim 17, wherein the selecting of the step size comprises:
selecting the step size of a greater amount as the difference is greater; and
selecting the step size of a lesser amount as the difference is less.

22. An operating method of a semiconductor device, the operating method comprising:
providing a word line with a verification voltage having a target level;
detecting a change in an output of a page buffer that senses a bit line of a memory cell connected to the word line; and
changing the verification voltage by a preset voltage level until the change is detected.

23. The operating method of claim 22, further comprising counting a number of times of the changing.

24. The operating method of claim 23, further comprising:
selecting a step size corresponding to the number of times; and
generating a program pulse based on the selected step size.

25. The operating method of claim 24, wherein the generating comprises increasing at least one of a voltage level of the program pulse and duration of the program pulse as the step size is greater.

26. The operating method of claim 24, wherein the generating comprises increasing a voltage level of the program pulse or duration of the program pulse as the step size is greater.

27. The operating method of claim 23, further comprising:
selecting a step size corresponding to the number of times; and
generating an erase pulse based on the selected step size.

28. The operating method of claim 27, wherein the generating comprises increasing at least one of a voltage level of the erase pulse and duration of the erase pulse as the step size is greater.

29. The operating method of claim 27, wherein the generating comprises increasing a voltage level of the erase pulse or duration of the erase pulse as the step size is greater.
